(19) United States
(12) Patent Application Publication
(10) Pub. No.: US 2002/0171107 A1
(43) Pub. Date: Nov. 21, 2002

(54) Method for forming a semiconductor device having elevated source and drain regions

(76) Inventors: Baohong Cheng, Austin, TX (US); Yeong-Jyh T. Lii, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 09/861,812

(22) Filed: May 21, 2001

(51) Int. Cl. H01L 21/00

(52) U.S. Cl. 257/347; 438/149

(57) ABSTRACT

Epitaxial silicon is grown to form elevated source/drain extensions for transistors on silicon-on-insulator (SOI) substrates. An offset linear layer is formed between the gate and the epitaxial silicon to prevent shorting. In one embodiment, the offset linear layer is a nitride and in another embodiment it is an oxide. The resulting structure decreases extension resistance and improves the scalability of SOI transistors by increasing the thickness of silicon underneath the source and drain regions, while keeping the silicon underneath the gate thin. This allows for the reduction in gate length without decreasing the functionality of the transistor.

### FIELD OF THE INVENTION

The invention relates generally to the field of semiconductor manufacturing and more specifically to elevated source and drain extensions.

### BACKGROUND OF THE INVENTION

The junction capacitance of semiconductor devices formed using bulk silicon substrates becomes too great as the desire for faster circuits increases. Therefore, the use of silicon-on-insulator (SOI) is desired in order to reduce junction capacitance and build faster circuits. As the gate length of the SOI transistors decreases, the silicon film thickness also decreases to maintain the device short channel performance, which results in an undesirable extension resistance increase. Therefore, a need exists for a transistor that decreases the extension resistance in SOI substrates.

### BRIEF DESCRIPTION OF THE DRAWINGS

FIG. 1 illustrates a cross-section of a semiconductor device formed using an SOI substrate as known in the prior art.

FIG. 2 illustrates a cross-section of a portion of a semiconductor device formed on an SOI substrate after offset liner formation in accordance with the present invention.

FIG. 3 illustrates a cross-section of a portion of a semiconductor device formed on an SOI substrate after epitaxial silicon is grown in accordance with the present invention.

FIG. 4 illustrates a cross-section of a portion of a semiconductor device formed on an SOI substrate during ion implantation to form source and drain regions in accordance with the present invention.

FIG. 5 illustrates a cross section of a portion of a semiconductor device formed on an SOI substrate after spacer liner and spacer formation in accordance with the present invention.

FIG. 6 illustrates a cross section of a portion of a semiconductor device formed on an SOI substrate after silicide formation in accordance with the present invention.

### DETAILED DESCRIPTION OF THE DRAWINGS

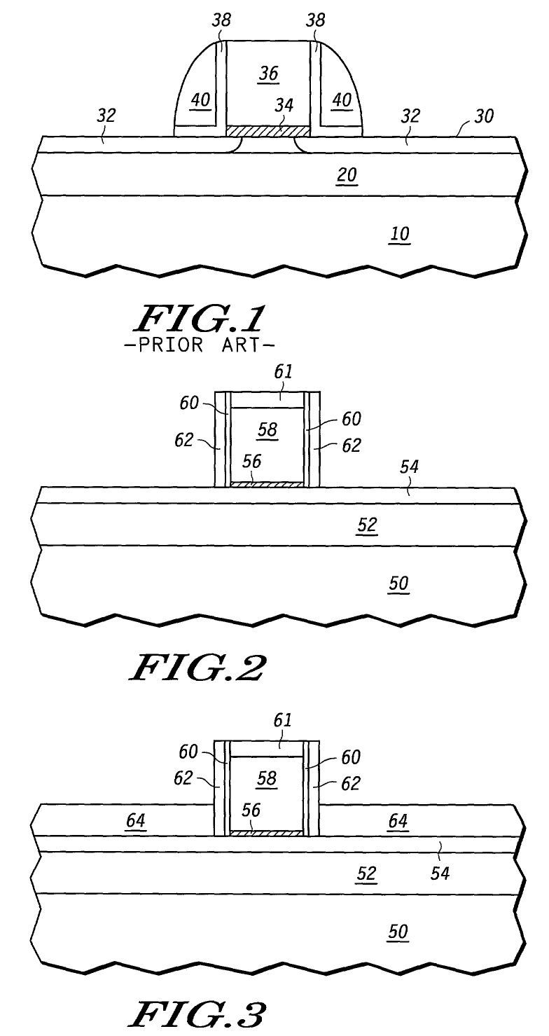

FIG. 1 illustrates a cross section of a semiconductor device including a gate 36, a gate dielectric 34 formed over a silicon-on-insulator (SOI) layer 30, which lies over a buried oxide (BOX) layer 20 and a silicon substrate 10 as known in the prior art. Spacer liners 38 and spacers 40 are formed around a gate 36 and over source and drain regions 32. Although using an SOI substrate decreases the junction capacitance, the transistor in FIG. 1 has an increased extension resistance within the source and drain regions 32 due to the thin SOI layer 30 underneath the spacers 40 and the spacer liners 38. This increases the channel resistance and, thus, decreases the performance of the device.

To decrease the extension resistance, in accordance with the present invention and as illustrated in FIGS. 2-6, an epitaxial silicon region is formed over an SOI layer 54, where a portion of the source and drain extensions are formed within this elevated area. This portion of the SOI layer 54 will be referred to herein as an active region. In order to isolate a gate electrode 58 during formation of epitaxial silicon layer 64 from the portions of SOI layer 54 that will subsequently be doped to form source and drain regions an offset liner 62 is necessary. Silicon substrates with SOI layers over BOX layers can be purchased. Alternatively, a BOX layer and a SOI layer can be formed on a silicon substrate. The invention is better understood by turning to the figures and is defined by the claims.

Turning to FIG. 2, the gate electrode 58, the gate dielectric 56, and the anti-reflective coating (ARC) layer 61 are formed and patterned over the SOI layer 54, the BOX layer 52 and the silicon substrate 50, which are all formed in previous processing steps known to one of ordinary skill in the art. In another embodiment, the SOI layer 54 and substrate 50 can be comprised of another semiconductor material. In a preferred embodiment the gate dielectric 56 is silicon dioxide. However, the gate dielectric 56 can also be silicon oxide, silicon oxynitride or a combination of the above. In another embodiment, the gate dielectric 56 can be a metal oxide such as hafnium oxide, zirconium oxide, aluminum oxide and the like. In a preferred embodiment the gate electrode 58 is polysilicon, which can be doped either N-type or P-type for NMOS and PMOS transistors, respectively. The gate electrode 58 can also comprise a metal, for example TiN. If the gate electrode 58 is polysilicon, a poly reoxidation (poly reox) process is performed after formation of the gate electrode 58 and the gate dielectric 56, resulting in a poly reox liner 60. However, if the gate electrode 58 is a metal gate, the poly reox process is not needed. The poly reox liner 60 is, typically, grown at approximately 900 degrees Celsius resulting in thickness of approximately 20 to 50 Angstroms.

Afterwards, an insulating layer (not shown) is deposited over gate electrode 58 using chemical vapor deposition (CVD), plasma enhanced chemical vapor deposition (PECVD), atomic layer deposition (ALD), and the like to result in good sidewall coverage of the gate electrode 58. Generally, the thickness of the insulating layer is about 50-250 Angstroms, or more specifically about 100-200 Angstroms. The insulating layer can be silicon oxynitride, silicon nitride, silicon dioxide or any other insulating material. Generally, the material chosen for the insulating layer includes oxygen and/or nitrogen.

An anisotropic etch is performed to pattern the insulating layer to form offset liner 62. As shown in FIG. 2, the offset liner is formed along the sidewalls of the gate electrode. The offset liner 62 will have a width approximately equal to the thickness of the insulating layer. Generally, the offset liner 62 has a width of about 50-250 Angstroms, or more specifically about 100-200 Angstroms. In one embodiment the anisotropic etch can be performed in a reactive ion etcher. The chemistry used for etching the dielectric layer is generally a fluorine-containing chemistry, such as CHF₃ and Ar. A skilled artisan acknowledges that the specific chemistry depends on the material chosen for the insulating layer.

Before growing epitaxial silicon for the elevated source/drain regions, a clean is, optionally, performed. The type and number of cleans varies depending on the thickness of the SOI layer 54 and the materials of the poly reox liner 60 and the offset liner 62. The thinner the SOI layer 54, generally, the more cleans are needed. For very thin (approximately less than 300 Angstroms) SOI regions 54, a five step cleaning process has been found to prepare the surface of the SOI layer 54 for subsequent epitaxial growth. The process used was an HF clean, an oxygen plasma including nitrogen tri-fluoride, a piranha clean, followed by a two-step clean process wherein the first step included NH₄OH, H₂O₂ and H₂O and the second step included H₂O₂, H₂O, and HCl, followed by a second HF clean. Performing just an HF and oxygen plasma, which includes nitrogen tri-fluoride, may be sufficient.

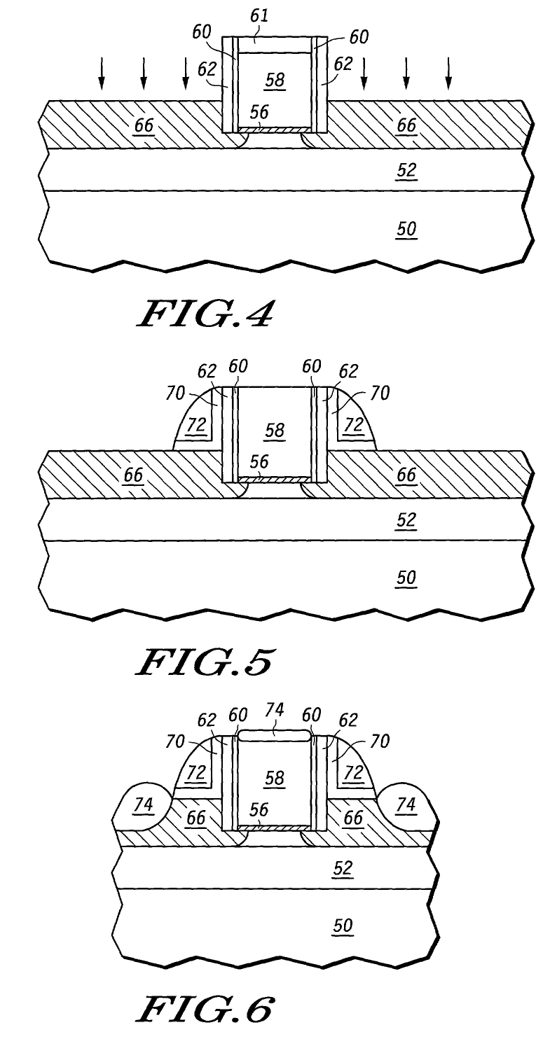

A selective epitaxial silicon process is performed at approximately 800 degrees Celsius in order to form epitaxial silicon over only the exposed silicon areas, as shown in FIG. 3. A temperature higher than 800 degrees Celsius can be used, however, the temperature is limited by the need for a selective epitaxial silicon process. Generally, epitaxial silicon layer 64 will be approximately 200-500 Angstroms. If the gate electrode 58 is polysilicon, the ARC 61 should not be removed prior to epitaxial silicon growth or else epitaxial silicon will grow on the exposed polysilicon surface, forming a mushroom-shaped gate. If the gate electrode 58 is TiN, or another metal gate material, it is possible to remove the ARC 61 prior to epitaxial silicon growth. (An explanation of the ARC 61 removal process will be explained later in regard to FIG. 4.)

As shown in FIG. 3, the epitaxial silicon layer 64 is separated from the gate electrode 58, gate dielectric 56 and the optional poly reox liner 60, if present, by the offset liner 62. Without the offset liner 62, the epitaxial silicon layer 64 would abut the gate electrode 58, and possibly the poly reox liner 60, causing a short between the gate electrode 58 and the source/drain regions 66.

As shown in FIG. 4, an ion implantation process is performed in order to form the source/drain region 66 within SOI layer 54 and the epitaxial silicon layer 64. Typical ion implantation species, such as boron or arsenic or phosphorous, are used and typical doses are used. In an alternate embodiment, the portion of source/drain regions 66 that lies within the SOI layer 54 can be formed by ion implantation prior to the epitaxial grown process. In this embodiment, a second ion implantation process is performed after growing the epitaxial silicon layer 64. Since this embodiment has two ion implantation processes as opposed to one in the preferred embodiment, the preferred embodiment decreases cycle time. Either can be performed.

As previously discussed, the ARC 61 is removed after the ion implantation process if gate electrode 58 is polysilicon, and can be removed after the formation of offset liner 62 if gate material 58 includes a metal. In a preferred embodiment, the ARC layer 61 is removed using a wet etch. In this embodiment, a portion of the offset liner 62 will be removed if the offset liner 62 is a nitride. This is advantageous because it may leave an air gap between the epitaxial silicon layers 64 and the gate electrode 58 and the poly reox liner 60, if present. The air gap will serve as a low dielectric constant material, thus reducing the capacitance between the gate electrode 58 and source/drain regions 66 and improving the performance of the device. Alternately, a dry etch can be used to remove the ARC 61.

A spacer liner layer 70 is then deposited using low-pressure chemical vapor deposition (LPCVD), PECVD, ALD and the like over the source/drain regions 66 and on a side of the gate electrode 58. In on embodiment, the spacer liner layer 70 is approximately a 100-500 Angstrom dielectric layer. The spacer liner material is typically traethylorthosilane (TEOS). However, any other dielectric material can be used. The spacer liner layer 70 can be a nitride, such as a silicon nitride, or another oxide material. In an embodiment where the spacer layer is an oxide, the deposition of a spacer liner layer 70 is not needed. Afterwards, an anisotropic etch is performed to form sidewall spacer 72, as shown in FIG. 5. The anisotropic etch can be performed by reactive ion etching and use the spacer liner layer 70 as an etch stop layer.

Next, a wet etch is performed in order to remove the portions of the spacer liner layer 70 that are not covered by the sidewall spacers 72. In the embodiment where the spacer liner layer 70 is an oxide, an anisotropic etch can be performed stopping on the epitaxial silicon layer 64. However, drawbacks of this embodiment are the possible damage of the epitaxial silicon layer from the etch and the substantial etching of the trench isolation region (not shown). In the embodiment, where the spacer liner layer 70 is an oxide, when removing the oxide during a wet etch, a portion of the trench isolation region will be removed, however, the amount of removal is not as great as in the second embodiment where the spacer is etched stopping on the epitaxial silicon layer 64. The resulting spacer liner 70 and the spacers 72 are shown in FIG. 5.

Afterwards, a salicide process is performed in order to reduce the contact resistance between the silicon regions and any subsequently formed plugs, which are usually tungsten. A metal such as titanium, cobalt or nickel is deposited using physical vapor deposition (PVD) followed by an anneal. In one embodiment, the anneal is a rapid thermal anneal (RTA). During this anneal the deposited metal will react with at least part of the epitaxial silicon layer 64 and, perhaps, part of the SOI layer 54 to form silicide layer 74 over source/drain regions 66. Generally, the silicide will only react with 100-200 Angstroms of the silicon. If the gate electrode 58 is polysilicon, silicide layer 74 will also be formed at the top of the gate electrode 58 due to the exposed polysilicon. Next, a wet etch is performed to remove any unreactive metal which exists over the non-silicon areas.

The elevated source/drain extensions decrease the extension resistance of the transistor by increasing the thickness of silicon underneath the source and drain regions, while keeping the silicon underneath the gate thin, such as less than 100 Angstroms. This allows for the reduction in gate length without degrading the short-channel performance of the transistor. While resulting in a desirable structure, the process of formation does not add any additional photolithography processes, which, typically, increase cycle time and cost dramatically.

Although the elevated source/drain extensions have been described in regards to a single gate structure on SOI, the structure can also be implemented into a double gate fully depleted metal-oxide semiconductor field effect transistor or a vertical double-gate SOI metal-oxide semiconductor field effect transistor, such as a FinFET. The source/drain extensions can also be implemented in a bulk semiconductor substrate, such as silicon, however, since the thickness of the semiconductor material in the substrate is significantly thick, there is little need to form additional semiconductor material.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for forming a semiconductor device, comprising:
forming a buried oxide layer on a surface of a silicon substrate;
forming an silicon-on-insulator (SOI) layer on the surface of the buried oxide layer;
forming a gate dielectric over the SOI layer;
forming a gate electrode on the gate dielectric and defining an active region around the gate electrode;
depositing an insulating layer over the gate electrode;
etching the insulating layer to form an offset liner around the gate electrode;
growing a silicon layer on the active region by epitaxial growth;
forming source/drain regions in the SOI layer;
forming an etch stop layer over the source/drain regions and on a side of the gate electrode;
forming a sidewall spacer over the etch stop layer; and
forming a silicide layer over the source/drain regions.

2. The method of claim 1, wherein depositing an insulating layer comprises depositing an insulating layer comprising an element selected from the group consisting of nitrogen and oxygen.

3. The method of claim 1, wherein etching the insulating layer comprises using an anisotropic etch.

4. The method of claim 1, further comprising forming an anti-reflective coating (ARC) over the gate electrode.

5. The method of claim 1, further comprising cleaning a surface of the active region prior to growing the silicon layer.

6. The method of claim 5, wherein cleaning the surface of the active region comprises using both hydrofluoric acid and oxygen plasma containing nitrogen tri-fluoride.

7. The method of claim 1, wherein etching the insulating layer comprises etching the insulating layer to form the offset liner having a width of about 50 to 250 angstroms.

8. A method for forming a silicon-on-insulator (SOI) semiconductor device, comprising:
depositing an insulating layer over a gate electrode;
etching the insulating layer to form an offset liner around the gate electrode;
growing a silicon layer on an active region of a semiconductor substrate by epitaxial growth;
forming source/drain regions in a SOI layer;
forming an etch stop layer over the source/drain regions and on a side of the gate electrode; and
forming a sidewall spacer over the etch stop layer.

9. The method of claim 8 further comprising forming a silicide layer over the source/drain regions.

10. The method of claim 8, wherein depositing an insulating layer comprises depositing a insulating layer comprising an element selected from the group consisting of nitrogen and oxygen.

11. The method of claim 8, wherein etching the insulating layer comprises using an anisotropic etch.

12. The method of claim 8, further comprising forming an anti-reflective coating (ARC) over the gate electrode.

13. The method of claim 8, further comprising cleaning a surface of the active region prior to growing the silicon layer.

14. The method of claim 13, wherein cleaning the surface of the active region comprises using both hydrofluoric acid and oxygen plasma containing nitrogen tri-fluoride.

15. The method of claim 8, wherein etching the insulating layer comprises etching the insulating layer to form the offset liner having a width of about 50 to 250 angstroms.

16. A semiconductor device, comprising:
a silicon-on-insulator (SOI) layer;
a gate electrode formed over the SOI layer;
an insulating layer formed over the gate electrode;
an offset liner formed along the sidewalls of the gate electrode by etching the insulating layer;
an epitaxial silicon layer grown on an active region of the SOI layer;
a source/drain region formed in the SOI layer; and
a sidewall spacer formed around the gate electrode.

17. The semiconductor device of claim 16 wherein the semiconductor device is characterized as being a double gate fully depleted metal-oxide semiconductor field effect transistor.

18. The semiconductor device of claim 16, wherein the semiconductor device is characterized as being a vertical double gate SOI metal-oxide semiconductor field effect transistor.

19. The semiconductor device of claim 16, further comprising a silicide layer formed over the source/drain region.

20. The semiconductor device of claim 16, wherein the insulating layer comprises an element selected from the group consisting of nitrogen and oxygen.

21. The semiconductor device of claim 16, wherein the offset liner has a width of about 50 to 250 Angstroms.
